(19) United States
(12) Patent Application Publication
(10) Pub. No.: US 2022/0082518 A1
(43) Pub. Date: Mar. 17, 2022

(54) METHOD OF MANUFACTURING MOLD, HOT WORKING MACHINE, OR DIE-CASTING MACHINE THEREOF

(71) Applicant: HITACHI METALS, LTD., Tokyo (JP)

(72) Inventors: Haruyuki MORI, Tokyo (JP); Masataka SATO, Tokyo (JP); Masayuki NAGASAWA, Tokyo (JP)

(73) Assignee: HITACHI METALS, LTD., Tokyo (JP)

(21) Appl. No.: 17/535,574

(22) Filed: Nov. 25, 2021

Related U.S. Application Data
(63) Continuation-in-part of application No. 16/337,406, filed on Mar. 28, 2019.

(30) Foreign Application Priority Data
Mar. 24, 2017 (JP) 2017-058648

(51) Int. Cl. G01N 25/72; B22C 9/00; G01N 1/44; G01N 1/42

(52) U.S. Cl. CPC G01N 25/72; G01N 1/42; G01N 1/44; B22C 9/00

(57) ABSTRACT

A method of manufacturing a mold by a machine tool, the method including predicting a thermal fatigue life of a mold which is made of a mold material having a hardness H and on which heating during contact with a workpiece and cooling after contact with a workpiece are repeated, the method including a step for obtaining a thermal stress maximum value σ_{h_MAX} among a plurality of thermal stress values at a position x on the mold and a temperature Tₕ at the thermal stress maximum value, wherein the temperature at the thermal stress maximum value σ_{h_MAX} is a temperature lower than a maximum temperature among the plurality of temperatures, the machine tool manufactures the predetermined mold shape from a mold material having one of the plurality of hardnesses in which the thermal fatigue life was obtained based on the thermal stress maximum value, the yield strength, and the contraction.

### CROSS-REFERENCE TO RELATED APPLICATION

This application is a continuation-in-part of U.S. application Ser. No. 16/337,406 filed on Mar. 28, 2019, which is a 371 application of the International PCT application serial no. PCT/JP2018/008922 filed on Mar. 8, 2018, which claims the priority benefit of Japan Patent Application No. 2017-058648, filed on Mar. 24, 2017. The entirety of each of the above-mentioned patent applications is hereby incorporated by reference herein and made a part of this specification.

### TECHNICAL FIELD

The present invention relates to a method of predicting a thermal fatigue life of a mold.

### BACKGROUND ART

In a mold whose work surface is used in contact with a workpiece with a high temperature such as a die-casting mold or a hot forging mold, since heating due to contact with the workpiece and cooling with a water-soluble mold release agent and a lubricant are performed, compression and tension thermal stress is applied to the surface of the mold. Thus, in an actual operation, since this thermal stress is repeatedly applied, thermal fatigue cracks occur in the surface of the mold, and, for example, on the work surface of the mold, the cracks are transferred to the workpiece. The transfer of cracks gradually becomes severe and when the mold becomes unusable, the mold is discarded. In particular, in a die-casting mold, cracks due to thermal fatigue are the most common reason for discarding, and it is strongly desired to improve a thermal fatigue life thereof.

In the related art, increasing the hardness of the mold and applying a mold material with improved high temperature strength were used in order to solve such problems, and the effect has actually been improved in some cases. However, since the relationships of the material properties and thermal stress load of a mold with a thermal fatigue life of the mold were unknown, it was unknown how long the life would be lengthened without actual application thereof. Therefore, the life was not lengthened as long as expected, trial and error were repeated, and time and cost were required for improvement in some cases.

Therefore, a method of predicting a thermal fatigue life of a mold according to material properties of the mold and a thermal stress distribution generated in the mold during use has been proposed (Patent Literature 1). That is, in the method, using a temperature Tₕ and a thermal stress σₕ during heating at a predetermined position x on the mold obtained according to the thermal stress distribution, a yield strength σ_{y}(Tₕ) at a predetermined mold hardness at the temperature Tₕ of the mold material and a contraction φ(T_{c}) at a predetermined mold hardness at a temperature T_{c} during cooling, according to the formula N={C₁(σ_{y}(Tₕ)/σₕ)^{m}·ln(1−φ(T_{c}))⁻¹−C₂}ⁿ, a thermal fatigue life N at a predetermined position x on the mold is predicted (C₁, C₂, m, and n are constants).

### CITATION LIST

### Patent Literature

### [Patent Literature 1]

Japanese Patent No. 4359794

### SUMMARY OF INVENTION

### Technical Problem

According to the method of Patent Literature 1, it is possible to efficiently find a hardness and a mold material of a mold suitable for improvement in a desired life without repeating prototyping of the mold, and thus it is possible to reduce time and cost consumed for improving a life of the mold.

However, in the case of Patent Literature 1, there is room for improvement in terms of increasing the accuracy of a predicted life of a mold with respect to an actual life of the mold.

An objective of the present invention is to provide a method of accurately predicting a thermal fatigue life of a mold.

### Solution to Problem

The present invention is a method of predicting a thermal fatigue life of a mold which is made of a mold material having a hardness H and on which heating during contact with a workpiece and cooling after contact with a workpiece are repeated, which includes obtaining a temperature distribution of a mold heated during contact with a workpiece; obtaining a distribution of thermal stress occurring in the mold according to the temperature distribution; obtaining a thermal stress maximum value σ_{h_MAX} at a position x on the mold and a temperature Tₕ at the thermal stress maximum value σ_{h_MAX} according to the thermal stress distribution; obtaining a yield strength σ_{y}(Tₕ) at the temperature Tₕ and a contraction φ(T_{c}) at a temperature T_{c} of the mold when it is cooled using the mold material having a hardness H; and substituting σ_{h_MAX}, σ_{y}(Tₕ) and φ(T_{c}) into the following relational formula, and thereby obtaining a thermal fatigue life N at a position x on the mold:

$$N = {\{ {{C}_{1} ( {σ}_{y} ( {T}_{h} ) \text{/} {σ}_{h \_ MAX} )}^{m} \cdot {ln ( 1 - φ ( {T}_{c} ) )}^{- 1} - {C}_{2} \}}^{n}$$

(C₁, C₂, m, and n are constants).

In the present invention, preferably, the temperature distribution of the mold and the distribution of thermal stress occurring in the mold are obtained whenever a use time of the mold reaches a time of 0.5 seconds or less

In addition, in the present invention, preferably, the position x on the mold is on a work surface having a corner radius of 2.0 mm or less.

### Advantageous Effects of Invention

According to the present invention, it is possible to predict a thermal fatigue life of a mold with accuracy.

### BRIEF DESCRIPTION OF DRAWINGS

FIG. 1 is a flowchart showing an example of a method of predicting a life of a mold according to the present invention.

FIG. 2 is a diagram showing a schematic partial cross-section obtained by dividing a mold into meshes using a finite element method and an example of a temperature distribution in the cross section.

FIG. 3 is a diagram showing a schematic partial cross-section obtained by dividing a mold into meshes using a finite element method and an example of a thermal stress distribution in the cross section.

FIG. 4 is a graph chart showing a relationship of transitions of a temperature and thermal stress at a specific position on a mold.

FIG. 5 is a diagram showing a shape of a mold used in an example.

FIG. 6 is an example of a temperature distribution diagram of a work surface of a mold which is created from a temperature distribution of an example.

FIG. 7 is an example of a thermal stress distribution diagram of a work surface of a mold which is created from a thermal stress distribution of an example.

FIG. 8 is a cross-sectional diagram showing cracks occurring in a V groove when a mold reaches a thermal fatigue life in actual die-casting using a mold used in an example.

### DESCRIPTION OF EMBODIMENTS

A feature of the present invention is that, for a value of a “thermal stress σₕ” used for obtaining a thermal fatigue life N at any position x on a mold, “the highest value” that is extracted from a thermal stress σₕ generated when the mold is heated is used.

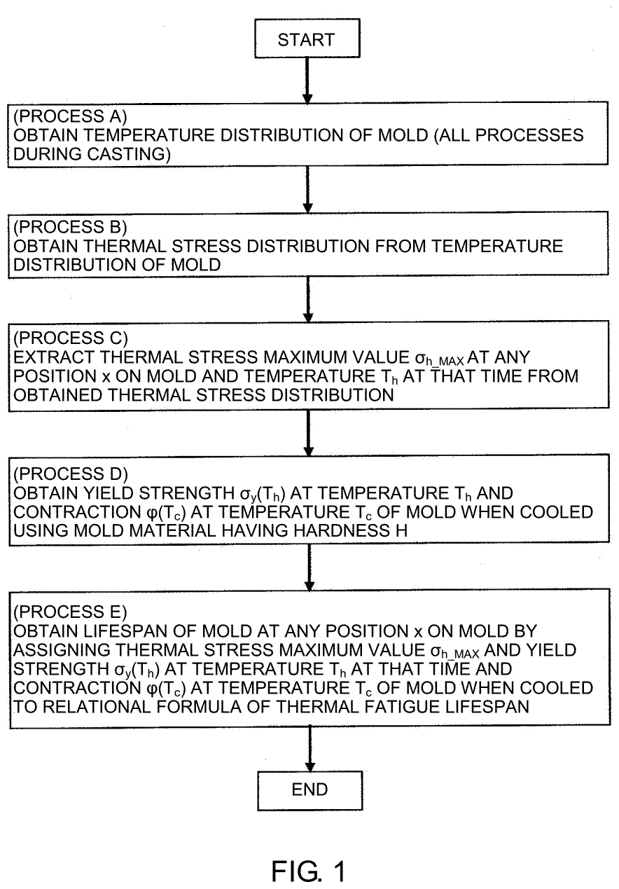

FIG. 1 shows all processes of a method of predicting a life of a mold according to one example of the present invention. The processes will be described below in detail.

(a) <Obtaining a Temperature Distribution of a Mold (Process A)>

First, it is necessary to know a hardness H of a mold in order to obtain a yield strength and a contraction of a mold material constituting a mold to be described below. Thus, during use of a mold which is made of a mold material having the hardness H and on which heating during contact with a workpiece and cooling after contact with a workpiece are repeated, a temperature distribution of the mold that is heated during contact with a workpiece is obtained. The hardness H can be a value at room temperature. Thus, for example, in the case of a die-casting mold, the temperature distribution is a series of temperature distributions of a mold from a state in which the mold is heated by injecting a molten metal into a cavity of the die-casting mold to a state in which a die-casting part after casting is removed from the cavity and the mold is cooled. The temperature distribution can be obtained by numerical calculation, for example, a finite difference method or a finite element method. In this case, as a premise for calculating a temperature distribution, values of physical properties of a mold material such as specific heat and thermal conductivity are used as necessary.

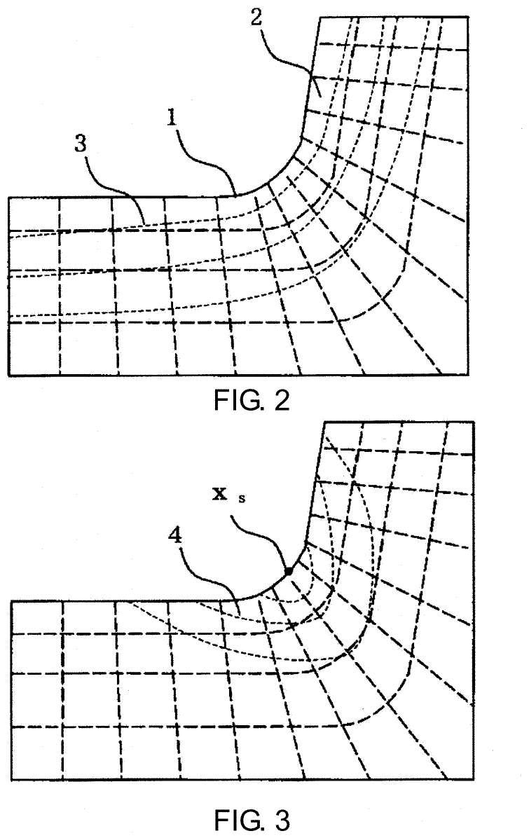

As an example, there is a method of obtaining a temperature distribution by the finite element method. FIG. 2 is a temperature distribution example of a cross section of a stress concentration part (recess) when a mold 1 is divided into meshes with split elements 2. The temperature distribution is indicated by a temperature isopleth 3. First, the entire mold is divided into meshes and heat load conditions are set. For a heat load, a heat transfer coefficient and an atmosphere temperature can be set and a heat flux can be set. In FIG. 2, for simplicity, the stress concentration part is shown two-dimensionally, but it can be three-dimensionally analyzed.

Next, heat transfer analysis of each element is performed, and a temperature distribution diagram is created from a calculation result. In this case, in order to improve the accuracy of predicting a life, it is preferable to optimize the calculation result by using the temperature that is actually measured in an actual mold for a temperature of the mold obtained in the calculation result. For example, it is possible to use a temperature that is actually measured on the surface of the actual mold. In order to measure a temperature of the surface of the actual mold, for example, a device configured to measure a temperature without contact such as an infrared thermographic device can be used. When the temperature of the mold obtained in the calculation result is different from the measured temperature, the heat load conditions can be re-examined and re-calculated.

(b) <Obtaining a Thermal Stress Distribution from the Temperature Distribution of the Mold Obtained in the Process A (Process B)>

Based on the temperature distribution diagram (FIG. 2), a distribution of thermal stress occurring in the mold is obtained by numerical calculation, for example, a finite element method. In this case, as a premise for calculating a thermal stress distribution, values of physical properties of the mold material such as various coefficients and a coefficient of linear expansion in the relationship between stress and strain are used as necessary.

First, since a model of the mold 1 is divided into meshes, a constraint condition is set for this. In this constraint condition, for example, according to a fixed state from the surroundings of the mold, a constraint direction or the like can be set for each side of the split elements 2.

Then, thermal stress analysis of the split elements 2 is performed, and a thermal stress distribution diagram can be created from the calculation result. FIG. 3 shows an example of the obtained thermal stress distribution diagram. The thermal stress distribution is indicated by a thermal stress isopleth 4. Further, the position “xₛ” indicates a stress concentration part.

(c) <Obtaining a Thermal Stress Maximum Value σ_{h_MAX} and a Temperature Tₕ at the Thermal Stress Maximum Value σ_{h_MAX} at any Position x on the Mold According to the Thermal Stress Distribution Obtained in the Process B (Process C)>

The method of Patent Literature 1 is very beneficial in predicting a life of a mold and selecting a hardness and a mold material of a mold suitable for increasing a desired life of the mold. However, in the method of Patent Literature 1, at any position x on the mold, for example, using a “time at which the temperature becomes the highest” of the mold during use of the mold as a reference, a life is computed from a relationship between a pair of a temperature field and a stress field generated “at the same time” as the time at which the temperature becomes the highest. In this case, in order to improve the accuracy of predicting a life of a mold, it is effective to actually designate the thermal stress σₕ used for the computation as “the highest value” of thermal stress generated during heating of the mold. Thereby, in an actual mold, a time at which the temperature becomes the highest at any position x differs for each position x. In addition, the time at which the temperature becomes the highest does not necessarily match a time at which the thermal stress becomes a maximum at the position x.

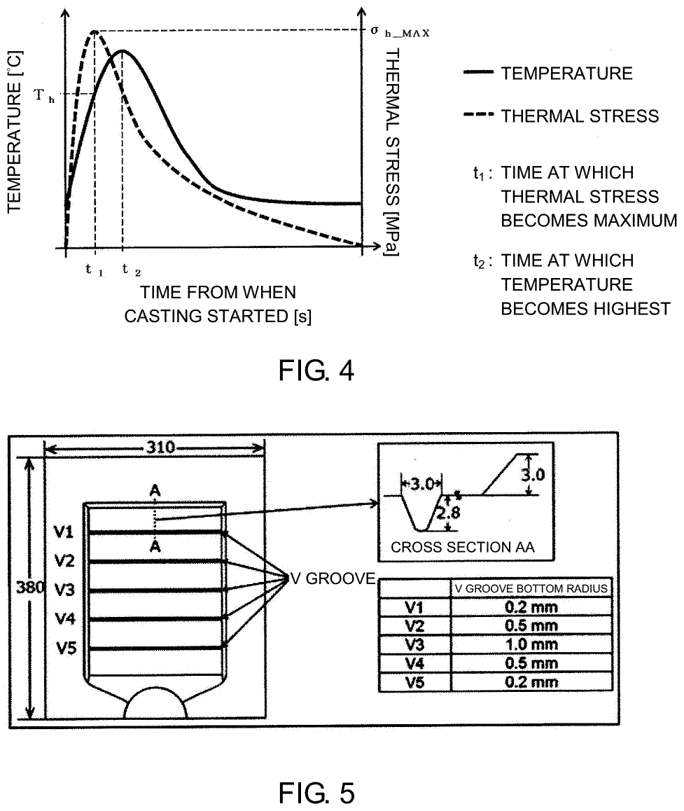

As an example, FIG. 4 shows a relationship of transitions of a temperature and thermal stress during use at a specific position on a surface (cavity surface) of a die-casting mold. The horizontal axis represents a time after the casting starts and the vertical axis represents the temperature and a thermal stress value. After the casting starts, the temperature of the surface of the mold increases and the thermal stress value also increases, and the thermal stress has a maximum value at a time t₁. However, the temperature then becomes a maximum at a time t₂. Since the thermal stress is determined exclusively by the surrounding temperature field, the thermal stress does not necessarily have a maximum value at a time at which the temperature becomes the highest at a specific position. Therefore, for example, after a series of thermal stresses occurring during casting is calculated, an operation of searching for and extracting the maximum value of the thermal stresses at positions at which a life is predicted is necessary.

In the method of predicting a life of a mold of the present invention, a relational formula to be described below is prepared, a value such as the thermal stress σₕ is substituted to obtain a thermal fatigue life N, and this life N varies according to the substituting value of the thermal stress σₕ. Therefore, in this point, in order to improve the accuracy of predicting a life of a mold, regarding a value of the thermal stress σₕ occurring in the mold during use, it is desirable to correctly select a maximum value thereof. Thus, for this purpose, without simply selecting a thermal stress value σₕ at a time at any position x on the mold using the time at which the temperature during use of the mold becomes the highest as a reference, it is necessary to compute a series of temperature fields and stress fields during its use cycle and extract a maximum value σ_{h_MAX} of the thermal stress from a series of thermal stresses σₕ. Further, the above temperature is not simply set to the above highest temperature, but it is necessary that it be a temperature Tₕ when the value of the thermal stress is a maximum value σ_{h_MAX}.

Here, for example, as shown in FIG. 4, in the relationship of transitions of the temperature and the thermal stress of the mold during use, a difference between the time t₁ when the thermal stress becomes a maximum and the time t₂ when the temperature becomes the highest may be small depending on a use form of the mold and the like. In such a case also, in order to improve the accuracy of predicting a life of a mold, it is effective if such a small difference can be recognized. In this case, in order to recognize such a small difference, obtaining the temperature distribution of the mold obtained in the process A and the distribution of thermal stress occurring in the mold obtained in the process B for each short elapsed time in a series of use times of the mold is effective. Thus, for example, the short elapsed time is preferably 0.5 seconds or less, more preferably 0.4 seconds or less, and most preferably 0.3 seconds or less. Thus, 0.2 seconds or less and 0.1 seconds or less are more preferable in that order.

(d) <Obtaining a Yield Strength σ_{y}(Tₕ) at the Temperature Tₕ and a Contraction φ(T_{c}) at a Temperature T_{c} of the Mold when the Mold is Cooled Using a Mold Material Having a Hardness H Constituting the Mold (Process D)>

Thus, in the method of predicting a life of a mold of the present invention, in order to obtain a thermal fatigue life N using a relational formula to be described below, the yield strength σ_{y}(Tₕ) and the contraction φ(T_{c}) of the mold are required. In this case, the yield strength σ_{y}(Tₕ) is a value at the temperature Tₕ. In addition, the contraction φ(T_{c}) is a value at the temperature T_{c} during cooling. Values of the yield strength σ_{y}(Tₕ) and the contraction φ(T_{c}) can be obtained by separately preparing a mold material having a hardness H. In this case, the hardness H can be set to a value at room temperature. Then, the values of the yield strength σ_{y}(Tₕ) and the contraction φ(T_{c}) that are measured in advance at various temperatures may be stored in a mechanical property database.

Here, the temperature T_{c} during cooling can be a surface temperature at a position x on the mold of which a life is predicted, for example, when an upper mold and a lower mold are opened, when the molded product is removed from the mold, when the mold is cooled, or the like in a process of removing a molded product (die-cast part) from the mold. In such a case, a surface temperature of the mold can be actually measured and this actual measurement value can be used. In addition, according to the finite element method or the like, in the same manner as above, calculation results can be used.

(e) <Obtaining a thermal fatigue life N at a position x on the mold by substituting values of σ_{h_MAX}, σ_{y}(Tₕ) and φ(T_{c}) into the relational formula

$$N = {\{ {{C}_{1} ( {σ}_{y} ( {T}_{h} ) \text{/} {σ}_{h \_ MAX} )}^{m} \cdot {ln ( 1 - φ ( {T}_{c} ) )}^{- 1} - {C}_{2} \}}^{n}$$

(C₁, C₂, m, and n are Constants) (Process E)>

Then, finally, values of the thermal stress maximum value σ_{h_MAX} at a position x on the mold, the yield strength σ_{y}(Tₕ) at the temperature Tₕ at that time, and the contraction φ(T_{c}) at the temperature T_{c} during cooling which are obtained in the processes A to D are substituted into a relational formula of a thermal fatigue life N, material properties, and thermal stress, and a life of the mold can be obtained. In this case, as the relational formula, a formula in Patent Literature 1 can be used. However, in the present invention, since the value of the thermal stress σₕ in the relational formula is set as the “maximum value σ_{h_MAX}” and the value of the yield strength σ_{y}(Tₕ) is set as the “value at the temperature Tₕ at which the thermal stress σ_{h_MAX} is reached,” the accuracy of predicting a life of a mold is improved.

In the present invention, for example, when the hardness of the mold is variously changed and realized, a relationship between the hardness and the life of the mold can be obtained, and an “optimal hardness” for a predetermined mold can be proposed.

While an example in which a life of “one mold” is predicted under specific mold shape and use conditions is shown in an example of the present invention, it is possible to obtain a relationship between molds made of various mold materials and lifes when lifes of a “plurality of molds” made of different mold materials are predicted under specific mold shape and use conditions. In addition, when a life of one mold is predicted by changing a mold shape (for example, a curvature radius of a corner part) and a use condition (such as a temperature of a workpiece), it is also possible to obtain a relationship between a mold shape and a use condition, and a life. Thereby, it is possible to propose an “optimal mold material” for a predetermined mold shape and use condition.

The present invention is most suitable for predicting a life of a mold in which a time at which the thermal stress becomes a maximum and a time at which the temperature becomes the highest at any position on the mold during use as described above are different from each other. Thus, such a time lag may occur in, for example, a corner (corner part) of a work surface, within the stress concentration part of the mold. Thus, in the present invention, for example, a position x on the mold is preferably on a work surface having a corner radius (corner R) of 2.0 mm or less. More preferably, 1.0 mm or less is used.

### Examples

Performing die-casting according to conditions in Table 1 was planned and a thermal fatigue life (the number of shots in which cracks occurred) of a mold when die-casting was actually performed was predicted. A mold used is as shown in FIG. 5 and it had a work surface having corner radiuses (bottom radius) with 5 V grooves.

TABLE 1

| Mold clamping force | | 350 tons |
|---|---|---|
| Casting cycle | | 51 seconds |
| Mold | Material | JIS-SKD61 |
| | Hardness | 44 HRC |
| | | (room temperature) |
| | Shape | 380 × 310 × 70 mm |
| | | (as shown in FIG. 5) |
| Molten metal | Type | ADC12 |
| | Temperature | 680° C. |

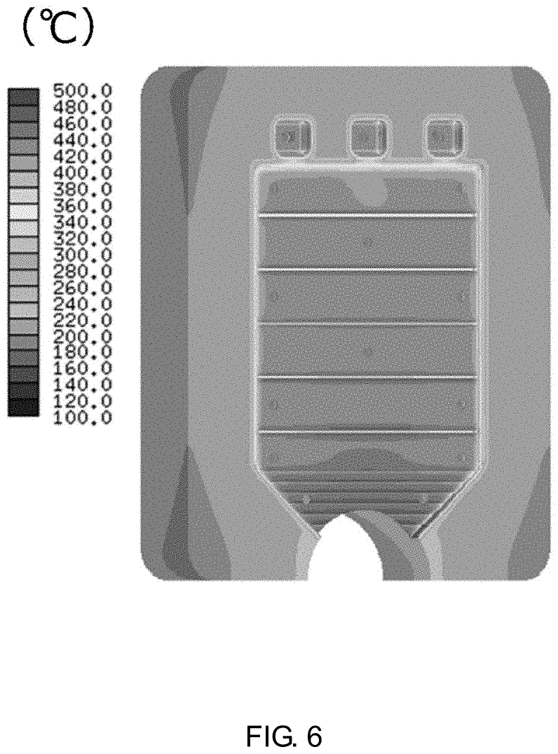

First, according to the above process (a), a temperature distribution of the mold in a series of casting cycles was obtained (process A). As an example of the temperature distribution diagram created from this calculation result, FIG. 6 shows a temperature distribution diagram of the work surface when 0.5 seconds has elapsed from when injection of a molten metal into a cavity was completed.

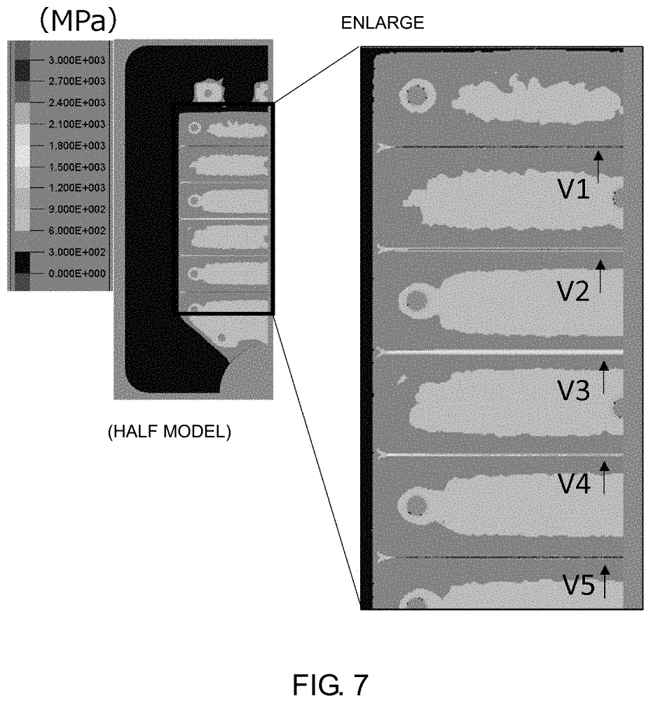

Next, according to the above process (b), a distribution of thermal stress occurring in the mold was obtained from the temperature distribution (process B). As an example of the thermal stress distribution diagram created from this calculation result, FIG. 7 shows a thermal stress distribution diagram of the work surface when 0.5 seconds has elapsed from when injection of a molten metal into a cavity was completed.

Then, according to the above process (c), according to the thermal stress distribution obtained above, as a position x on the mold, at positions of the bottom of V grooves (V1 to V5) provided on the work surface of the mold as the stress concentration part, a thermal stress maximum value σ_{h_MAX} and the temperature Tₕ at the thermal stress maximum value a Max were obtained (process C). In this case, as a comparative example, in order to perform a method of predicting a thermal fatigue life of a mold in Patent Literature 1, at positions of the bottom of V grooves, a temperature maximum value T_{h_MAX} and the thermal stress σₕ at the temperature maximum value T_{h_MAX} were obtained.

In addition, according to the above process (d), using a mold material (JIS-SKD61) having a hardness of 44 HRC at room temperature, the yield strength σ_{y}(Tₕ) at the temperature Tₕ and a contraction φ(T_{c}) at the temperature T_{c} of the mold that was cooled were obtained. In this case, as a numeric value used in the comparative example, a yield strength σ_{y}(T_{h_MAX}) at the temperature T_{h_MAX} was also obtained. The results regarding the V grooves are shown in Table 2.

TABLE 2

| | σ_{y}(Tₕ) | σ_{y}(Tₕ_MAX) | T_{c} | ϕ(T_{c}) |
|---|---|---|---|---|
| | (MPa) | (MPa) | (° C.) | (%) |
| V1 | 997 | 997 | 191 | 51.2 |
| V2 | 994 | 991 | 193 | 51.2 |
| V3 | 931 | 931 | 195 | 51.3 |
| V4 | 985 | 985 | 195 | 51.3 |
| V5 | 979 | 979 | 201 | 51.4 |

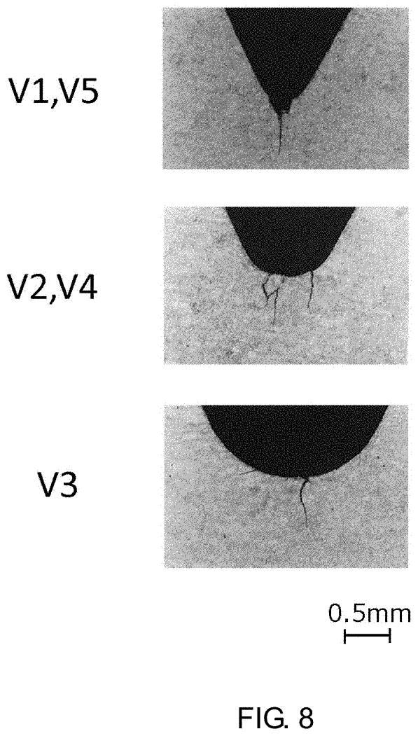

Then, according to the above process (e), values of the constants C₁, C₂, m, and n of the relational formula of “N={C₁(σ_{y}(Tₕ)/σ_{h_MAX})^{m}·ln(1−φ(T_{c}))⁻¹−C₂}ⁿ” were appropriately determined according to a level of cracks when the life was reached shown in FIG. 8, and values of σ_{h_MAX}, σ_{y}(Tₕ) and φ(T_{c}) or values of σₕ, σ_{y}(T_{h_MAX}), and φ(T_{c}) were substituted into the relational formula, and thereby thermal fatigue lifes N on the bottom with V grooves were obtained by methods of predicting a thermal fatigue life of a mold according to the example of the present invention and the comparative example.

In the present embodiment of the disclosure, the following constants for C₁, C₂, m, and n were used.

$$C 1 = 179.12$$

$$C 2 = 1.48$$

$$m = 1$$

$$n = 2$$

The constants used illustrates one example only, and the disclosure is not limited thereto. The constants may be other values according to requirements.

Then, these predicted values of the thermal fatigue life N were compared with a thermal fatigue life N (that is, a thermal fatigue life N when cracks shown in FIG. 8 occurred on the bottom of the V grooves) when die-casting was actually performed under conditions in Table 1. The results are shown in Table 3.

TABLE 3

| | | | | | | | Thermal fatigue life (N) | | |
|---|---|---|---|---|---|---|---|---|---|
| | | | | | | | Example | | |
| | | Elapsed time (s) | | | | | of present | Comparative | |
| | | 0.31 | 0.40 | 0.50 | 0.60 | 0.74 | invention | example | Actual |
| V1 | Temperature | 396.4 | 402.6 | ^{*1}407.2 | 407.2 | 396.8 | 1,232 | 1,232 | 2,130 |
| | (° C.) | | | | | | | | |
| | Thermal | 3,277 | 3,440 | ^{*2}3,503 | 3,425 | 3,211 | | | |
| | stress (MPa) | | | | | | | | |
| V2 | Temperature | 399.2 | 405.0 | 409.6 | ^{*1}411.1 | 402.3 | 2,328 | 2,383 | 2,130 |
| | (° C.) | | | | | | | | |
| | Thermal | 2,387 | 2,509 | ^{*2}2,570 | 2,537 | 2,385 | | | |
| | stress (MPa) | | | | | | | | |
| V3 | Temperature | 451.7 | 454.9 | ^{*1}455.0 | 449.5 | 427.6 | 3,325 | 3,325 | 3,983 |
| | (° C.) | | | | | | | | |
| | Thermal | 1,920 | 1,994 | ^{*2}2,028 | 1,985 | 1,835 | | | |
| | stress (MPa) | | | | | | | | |
| V4 | Temperature | 403.7 | 409.0 | 413.2 | ^{*1}415.8 | 410.7 | 2,055 | 2,055 | 1,553 |
| | (° C.) | | | | | | | | |
| | Thermal | 2,496 | 2,624 | 2,704 | ^{*2}2,711 | 2,579 | | | |
| | stress (MPa) | | | | | | | | |
| V5 | Temperature | 408.9 | 413.8 | 417.4 | ^{*1}420.1 | 417.4 | 1.180 | 1,180 | 970 |
| | (° C.) | | | | | | | | |
| | Thermal | 3,278 | 3,419 | 3,513 | ^{*2}3,537 | 3,401 | | | |
| | stress (MPa) | | | | | | | | |

^{*1}: Tₕ_MAX
^{*2}: σₕ_MAX

Based on the results in Table 3, at positions of the bottom of all V grooves, in a range of 0.31 to 0.74 seconds after injection of a molten metal into the cavity was completed, the thermal stress maximum value σ_{h_MAX} and the temperature maximum value Tₕ MAX were confirmed. Then, according to calculation, an occurrence time of the σ_{h_MAX} and T_{h_MAX} matched at V grooves except for V2 a time of 0.50 seconds elapsed or 0.60 seconds elapsed after injection of a molten metal was completed, and the occurrence time was shifted at V2. As a result, at V2, in the method of predicting a thermal fatigue life of a mold in the example of the present invention and the method of predicting a thermal fatigue life of a mold in the comparative example, the values of the predicted thermal fatigue life were different from each other. Thereby, the value of the thermal fatigue life obtained in the method of predicting a thermal fatigue life of a mold in the example of the present invention was close to the value of the actual thermal fatigue life.

A relationship between the hardness and the thermal fatigue life of a predetermined mold shape may be obtained for a plurality of hardnesses. In addition, a relationship between the mold material having the hardness and the thermal fatigue life of a predetermined mold shape may be obtained for a plurality of mold materials. Since the thermal fatigue life (N) may be more accurately calculated using the thermal stress maximum value σ_{h_MAX} as described above, a mold material having a hardness that satisfies a user's thermal fatigue life requirements may be more accurately determined.

For example, if a more cost effective mold material is determined to satisfy the thermal fatigue life requirements of a particular application, then a more expensive mold material does not need to be used for manufacturing the mold and the cost may be reduced. Or for example, the mold material providing the longest thermal fatigue life may be selected to manufacture the mold if a long thermal fatigue life is required. Accordingly, a machine tool may then be used to manufacture the predetermined mold shape from the mold material having the hardness that satisfies the user's thermal fatigue life requirements.

Furthermore, an example of a machine tool may be a CNC machine. However, the disclosure is not limited thereto. In addition, the mold manufactured by the machine tool may be mounted to a hot working machine or a die-casting machine. The hot working machine and the die-casting machine may be, for example, an injection molding machine.

1. A method of manufacturing a mold by a machine tool, the method comprising:
predicting a thermal fatigue life of a mold which is made of a mold material having a hardness H and on which heating during contact with a workpiece and cooling after contact with a workpiece are repeated, the step for predicting the thermal fatigue life comprising:
a step for obtaining a temperature distribution of a mold heated during contact with a workpiece by acquiring a temperature at different positions of the mold during a passage of time;
a step for obtaining a distribution of thermal stress corresponding to the passage of time occurring in the mold according to the temperature distribution;
a step for obtaining a plurality of thermal stress values at a plurality of positions on the mold, and obtaining a plurality of temperatures corresponding to the plurality of thermal stress values;
a step for obtaining a thermal stress maximum value σ_{h_MAX} among the plurality of thermal stress values at a position x on the mold and a temperature Tₕ at the thermal stress maximum value σ_{h_MAX} according to the thermal stress distribution, wherein the temperature Tₕ at the thermal stress maximum value σ_{h_MAX} is a temperature lower than a maximum temperature among the plurality of temperatures;
a step for obtaining by using the mold material having the hardness H, a yield strength σ_{y}(Tₕ) of the temperature Tₕ and a contraction φ(T_{c}) of a temperature T_{c} at which the mold is cooled; and
a step for obtaining a thermal fatigue life N at a position x on the mold based on the thermal stress maximum value σ_{h_MAX}, the yield strength σ_{y}(Tₕ), and the contraction φ(T_{c}),
wherein a relationship between the hardness and the thermal fatigue life of a predetermined mold shape is obtained for a plurality of hardnesses using the step of predicting the thermal fatigue life, and
the machine tool manufactures the predetermined mold shape from a mold material having one of the plurality of hardnesses in which the thermal fatigue life was obtained based on the thermal stress maximum value σ_{h_MAX}, the yield strength σ_{y}(Tₕ), and the contraction φ(T_{c}).

2. The method of manufacturing the mold according to claim 1, wherein the temperature distribution of the mold and the distribution of thermal stress occurring in the mold are obtained whenever a use time of the mold reaches a time of 0.5 seconds or less.

3. The method of manufacturing the mold according to claim 1, wherein the position x on the mold is on a work surface having a corner radius of 2.0 mm or less.

4. The method of manufacturing the mold according to claim 2, wherein the position x on the mold is on a work surface having a corner radius of 2.0 mm or less.

5. A method of operating a hot working machine or a die-casting machine, comprising a step of mounting the mold manufactured by the method according to claim 1 to the hot working machine or the die-casting machine.

6. A method of manufacturing a mold by a machine tool, the method comprising:
predicting a thermal fatigue life of a mold which is made of a mold material having a hardness H and on which heating during contact with a workpiece and cooling after contact with a workpiece are repeated, the step for predicting the thermal fatigue life comprising:
a step for obtaining a temperature distribution of a mold heated during contact with a workpiece by acquiring a temperature at different positions of the mold during a passage of time;
a step for obtaining a distribution of thermal stress corresponding to the passage of time occurring in the mold according to the temperature distribution;
a step for obtaining a plurality of thermal stress values at a plurality of positions on the mold, and obtaining a plurality of temperatures corresponding to the plurality of thermal stress values;
a step for obtaining a thermal stress maximum value σ_{h_MAX} among the plurality of thermal stress values at a position x on the mold and a temperature Tₕ at the thermal stress maximum value σ_{h_MAX} according to the thermal stress distribution, wherein the temperature Tₕ at the thermal stress maximum value σ_{h_MAX} is a temperature lower than a maximum temperature among the plurality of temperatures;
a step for obtaining by using the mold material having the hardness H, a yield strength σ_{y}(Tₕ) of the temperature Tₕ and a contraction φ(T_{c}) of a temperature T_{c} at which the mold is cooled; and
a step for obtaining a thermal fatigue life N at a position x on the mold based on the thermal stress maximum value σ_{h_MAX}, the yield strength σ_{y}(Tₕ), and the contraction φ(T_{c}),
wherein a relationship between the mold material having the hardness and the thermal fatigue life of a predetermined mold shape is obtained for a plurality of mold materials using the step of predicting the thermal fatigue life, and
the machine tool manufactures the predetermined mold shape from one of the plurality of mold materials in which the thermal fatigue life was obtained based on the thermal stress maximum value σ_{h_MAX}, the yield strength σ_{y}(Tₕ), and the contraction φ(T_{c}).

7. The method of manufacturing the mold according to claim 6, wherein the temperature distribution of the mold and the distribution of thermal stress occurring in the mold are obtained whenever a use time of the mold reaches a time of 0.5 seconds or less.

8. The method of manufacturing the mold according to claim 6, wherein the position x on the mold is on a work surface having a corner radius of 2.0 mm or less.

9. The method of manufacturing the mold according to claim 7, wherein the position x on the mold is on a work surface having a corner radius of 2.0 mm or less.

10. A method of operating a hot working machine or a die-casting machine, comprising a step of mounting the mold manufactured by the method according to claim 6 to the hot working machine or the die-casting machine.
